(19) United States
(12) Patent Application Publication
(10) Pub. No.: US 2016/0037689 A1
(43) Pub. Date: Feb. 4, 2016

(54) INTELLIGENT COMBINATION-TYPE ENERGY-SAVING CABINET

(71) Applicant: GUANGZHOU HOLDSTORM SCIENCE & TECHNOLOGY CO., LTD., Guangzhou (CN)

(72) Inventor: Xiaole Fu, Guangzhou (CN)

(21) Appl. No.: 14/881,175

(22) Filed: Oct. 13, 2015

Related U.S. Application Data
(63) Continuation-in-part of application No. 13/581,970, filed on Oct. 4, 2013.

(30) Foreign Application Priority Data
Jan. 25, 2011 (CN) 201110026991.7
Apr. 21, 2015 (CN) 201510192486.8

(51) Int. Cl. H05K 7/20

(52) U.S. Cl. CPC H05K 7/20836; H05K 7/20736

(57) ABSTRACT

The invention relates to an intelligent combination-type energy-saving cabinet, comprising: one or more cabinet bodies; a main air pipe of an air conditioner connected with the air conditioner and each the cabinet body, the air conditioner, the main air pipe of the air conditioner and the cabinet body constituting one sealed air-circulation system; and a two-dimension dynamic air-transport energy-saving system for regulating the air transport of the sealed air-circulation system constituted by the air conditioner, the main air pipe of the air conditioner and the cabinet body. The invention greatly reduces the energy consumption of the air conditioner and obtains the objects of energy saving and environmental protection.

### CROSS REFERENCE TO RELATED APPLICATIONS

The present application is a Continuation-in-part application of U.S. application Ser. No. 13/581,970 filed on Oct. 4, 2013, which is national phase application of PCT application No. PCT/CN2011/000887 filed on May 23, 2011, which claims the benefit of Chinese patent application No. 201110026991.7 filed on Jan. 25, 2011. The present application also claims the benefit of Chinese patent application No. 201510192486.8 filed on Apr. 21, 2015. All the above are hereby incorporated by reference.

### FIELD OF THE INVENTION

The invention relates to the technical field of a cabinet, in particular to an intelligent combination-type energy-saving cabinet.

### BACKGROUND OF THE INVENTION

At present, a larger data center and a machine room are usually equipped with cabinets, the cooling power of a heat-dissipation air conditioner of an apparatus in the cabinets and the fire-fighting gas should be set in accordance with the area and volume of the machine room. Therefore, there are the following shortcomings:

To meet the needs of the apparatus, the air conditioner should be precisely in air conditioning under constant temperature and constant humidity state, due to the larger space of the machine room, the dissipation and conduction of cold energy is large, thus requiring large power of an air conditioner, and resulting in large power consumption, which is not conducive to energy conservation, and hence is waste of energy.

### SUMMARY OF THE INVENTION

The technical problem solved by the invention is to provide an intelligent combination-type energy-saving cabinet. The invention is realized through the following technical solution:

The invention relates to an intelligent combination-type energy-saving cabinet comprising:

one or more cabinet bodies;

a main air pipe of an air conditioner connected with the air conditioner and each the cabinet body, the air conditioner, the main air pipe of the air conditioner and the cabinet body constituting one sealed air-circulation system; and

a two-dimension dynamic air-transport energy-saving system for regulating the air-transport of the sealed air-circulation system constituted by the air conditioner, the main air pipe of the air conditioner and the cabinet body;

wherein the inner portion of the cabinet body is divided into an air-transport area, a heat exchange area and an air-return area, a plurality of apparatuses are placed at the heat exchange area;

the two-dimension dynamic air-transport energy-saving system comprises:

an area-division module for dividing the air-transport area into at least two sub air-transport units according to the number of the apparatuses at the heat exchange area and a heat load in a vertical direction, and correspondingly providing at least two sub air-return units at the air-return area;

a collection module for collecting the temperature of the sub air-transport unit and of the sub air-return unit as well as the heat load of the apparatus at the heat exchange area, and transmitting collected data to a following processing module; and

the processing module for regulating the air transport quantity of each the sub air-transport unit in a horizontal direction and the air transport quantity of the air-transport area in the vertical direction in the real time according to the collected data and the preset data.

Furthermore, the processing module is also used for regulating the air-return quantity of each the sub air-return unit according to the collected data and the preset data in the real time according to the collected data and the preset data.

Furthermore, the processing module specifically comprises:

a first sub processing unit for regulating the air-transport quantity according to the relation between a preset heat load and the air-transport quantity in the real time, wherein the relation between the air-transport quantity and the heat load is shown in the following formula:

V=−2.80Q²+209.17Q−79.4

wherein V is the air-transport quantity of a system, and its unit is m³/h; Q is the heat load, and its unit is kw.

Furthermore, the processing module specifically comprises:

a second processing unit is used for regulating the air-transport quantity of the sub air-transport unit in the horizontal direction according to the air-transport quantity of the air-transport area in the vertical direction;

the relation between an air-transport pressure of a refrigeration system and the heat load in the cabinet is shown in the following:

ΔP=14.37+0.81Q

wherein ΔP is the air-transport pressure of the refrigeration system, and its unit is Pa; Q is the heat load in the cabinet, and its unit is kw.

For the intelligent combination-type energy-saving cabinet of the invention, as the apparatus is placed in the cabinet, and the air conditioner, the main air pipe of the air conditioner and the cabinet body constitute one sealed air-circulation system, the air conditioner only needs to refrigerate the air in the sealed system to obtain the working environment under the constant temperature and humidity needed by the apparatus, which can be considered according to the space and volume in the cabinet, for the space of the machine room outside of the cabinet, a common air conditioner can be used, this makes the power and energy consumption of an air conditioning in a large data center be greatly reduced and hence can save energy. Furthermore, the two-dimension dynamic air-transport energy-saving system of the invention divides the air-transport area into at least two sub air-transport units according to the apparatus at the heat exchange area in the vertical direction, provides the sub air-return unit at the air-return area correspondingly, then collects the temperature of the sub air-transport unit and of the sub air-return unit as well as the heat load of the apparatus at the heat exchange area in the real time, and regulates the air-transport quantity of each the sub air-transport unit in the horizontal direction, the air-transport quantity of the air-transport area in the vertical direction and/or the air-return quantity of each the sub air-return unit according to the collected data and the preset data in the real time. This optimizes air-transport efficiency, therefore, under the premise of obtaining the temperature needed by each the apparatus in the heat exchange area, the energy consumption of the air conditioner is greatly reduced, thus achieving the object of energy saving and environmental protection.

### BRIEF DESCRIPTION OF THE DRAWINGS

In order to be described easily, the invention is described with the following preferred examples and figures in details.

FIG. 1 is a structural perspective drawing of an intelligent combination-type energy-saving cabinet of the invention.

FIG. 2 is a diagram that an intelligent combination-type energy-saving cabinet of the invention is mounted on a floor.

FIG. 3 is a structural block diagram of a two-dimension dynamic air-transport energy-saving system of the invention.

FIG. 4 is a diagram of an intelligently controlled model according to an example of a two-dimension dynamic air-transport energy-saving system of the invention.

FIG. 5 is a diagram according to an example of a two-dimension dynamic air-transport energy-saving system of the invention.

FIG. 6 is a diagram of a change relation between an air-transport quantity and a heat load according to an example of a two-dimension dynamic air-transport energy-saving system of the invention.

FIG. 7 is a diagram of a relation between an air-transport quantity as well as a heat load and an air-transport pressure according to an example of a two-dimension dynamic air-transport energy-saving system of the invention.

FIG. 8 is a diagram of a change relation between a starting critical point and a heat load according to an example of a two-dimension dynamic air-transport energy-saving system of the invention.

FIG. 9 is a diagram of a change relation between a power consumption of a system and a heat load according to an example of a two-dimension dynamic air-transport energy-saving system of the invention.

### DETAILED DESCRIPTION OF THE PREFERRED EMBODIMENT

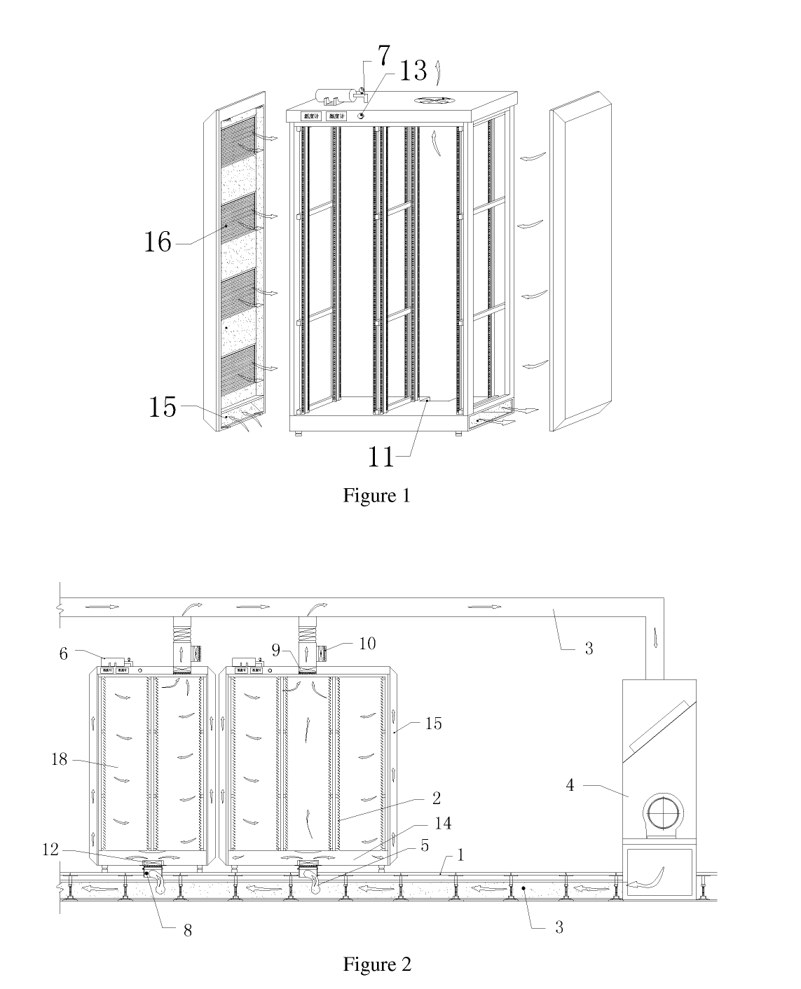

Referring to FIG. 1 and FIG. 2, an intelligent combination-type energy-saving cabinet of the invention is placed on a floor 1 of a cabinet room and includes: one or more cabinet bodies 2 which can be designed and produced according to a providing type of a use apparatus, is a detachable combination mounting body itself, is manufactured according to the room of the cabinet based on a general standard generally, and can be designed and manufactured according to the type of the apparatus and the size of an outer frame under a special case; a main air pipe 3 of an air conditioner connected with the air conditioner 4 and each the cabinet body 2; one or more branch air pipes 5 of the air conditioner provided between the main air pipe 3 of the air conditioner and the cabinet body 2; a fire-fighting cylinder 6 provided over each the cabinet body 2 and stored with a fire-extinguishing insert gas; an air-intake pipe 7 provided between the fire-fighting cylinder 6 and the cabinet body 2; a blower 8 provided under each the cabinet body 2; an air-return machine 9 provided over each the cabinet body 2; a smoke-exhaust valve 10 provided over each the air-return machine 9; inlet and outlet lines 11 of strong and weak currents of an apparatus which are provided under each the cabinet body 2; a detachable cover plate which is used for sealing the inlet and outlet lines of the strong and weak currents of the apparatus, hence makes the pressure in the cabinet body be larger than the pressure of the outside portion of the cabinet body, and can effectively prevent the cold air from flowing out of the cabinet body from the inner portion of the cabinet body; an air-pressure released safe hole for being provided on the detachable cover plate and mounting a pressure released valve to prevent the pressure in the cabinet body from being too large when the fire-extinguishing insert gas is ejected; and a control system for precisely controlling the constant temperature and humidity, fire-fighting and fire-extinguishing in the cabinet body. The control system includes a temperature sensor, a humidity sensor, a smoke sensor and other electrical components (all of which are not shown), a thermometer and a hygrometer (all of which are not shown) which are connected with the control system are also provided outside of the cabinet body 2, the temperature and humidity inside the cabinet body 2 can be observed.

Wherein an air deflector 12 of the air conditioner is provided at the connection portion of the branch air pipe 5 of the air conditioner and the cabinet body 2, and the blower 8 is provided under the air director 12 of the air conditioner.

When a fire occurs inside some cabinet body 2, the control system will automatically close the corresponding blower 8 and the corresponding air-return machine 9; the fire-fighting cylinder 6 will eject an insert gas to ensure the pressure of the fire-extinguishing gas inside the cabinet so that the fire extinguishing is carried out in the cabinet body 2, thereby avoiding that because the fire-extinguishing gas inside the machine room instantaneously goes into eruption when the partial cabinet gives a fire alarm, other apparatuses in the cabinet are seriously damaged and the staff who do not have time to escape suffer from suffocation to have their lives be endangered.

A fire-extinguishing valve 13 is provided at the side of the fire-fighting cylinder 6 which can control the discharge of the insert gas manually or automatically. After the fire alarm is finished, the smoke-exhaust valve 10 over the air-return machine 9 can operate at the set time to discharge the fire-extinguishing gas and smoke.

A bottom air-intake groove 14 communicated with the branch air pipe 5 of the air conditioner is provided at the bottom of the cabinet body, and a side air-intake groove 15 connected with the bottom air-intake groove 14 is provided at the two sides of the cabinet body 2; the side air-intake groove 15 is provided with an air shutter 16 of the air conditioner which sends the air into the cabinet, the air of the air conditioner passes through the branch air pipe 5 of the air conditioner via the main air pipe 3 of the air conditioner, then through the bottom air-intake groove 14 and the side air-intake groove 15, and into the cabinet via the air shutter 16 of the air conditioner, according to the temperature and humidity in the cabinet, the control system automatically adjusts the blower 8 and the air-return machine 9 to control the air-transport quantity and the air-return quantity, so as to control the temperature and humidity in the cabinet. Two air-pressure released safe holes are provided on the cover plate of the inlet line to mount the pressure released valve to avoid the damage caused by the excessive pressure in the cabinet when the fire-extinguishing gas goes into eruption.

The separate power control and point-to-point fire extinguishing of the combination-type safe cabinet of the invention has the following advantages: when the apparatus of some cabinet breaks out of fire, the working power supply of the apparatus of the cabinet will automatically power off not to affect the normal operation of other cabinets, at the moment, the fire-extinguishing system of the cabinet is activated to carry out the fire extinguishing for the range of the cabinet, thereby greatly reducing gas consumption and realizing accurate fire extinguishing; the most important thing is to avoid the waste caused by all of the fire-extinguishing gases going into eruption instantaneously when the fire alarm occurs, the local fire is avoided to affect the apparatuses of the whole machine room to halt or be scrapped, to interrupt a network and cause the data to be lost, and cause the staff who do not have time to escape to suffer from suffocation and be endangered, thus having the advantages of energy saving and security.

A transparent fire-fighting safe heat-insulating glass door 18 is mounted outside of the cabinet body 2 so that the apparatus can be conveniently maintained and the use state of the apparatus can be observed. The inlet line is also provided under the cabinet body 2. The control for the temperature and humidity, the fire fighting, the fire extinguishing and an interlocking system of a power technology are all intelligently and automatically controlled and should have auxiliary manual control. The structure of the cabinet itself is in a split-body standard modularization combination mounting type, thus having convenient maintenance as well as easy transport and handling.

For the intelligent combination-type energy-saving cabinet of the invention, as the apparatus is placed in the cabinet, and the air conditioner, the main air pipe of the air conditioner and the cabinet body constitute one sealed air-circulation system, the air conditioner only needs to refrigerate the air in the sealed system to obtain the working environment under the constant temperature and humidity needed by the apparatus, which can be considered according to the space and volume in the cabinet, for the space of the machine room outside of the cabinet, a common air conditioner can be used, this makes the power and energy consumption of an air conditioning in a large data center be greatly reduced and hence can save energy. Meanwhile, the fire extinguishing of the gas can be provided according to the space and volume of the separate cabinet, thus reducing the affecting range of the fire and realizing the accurate fire extinguishing; for the fire extinguishing of the space of the machine room outside of the cabinet, the common air conditioner can be used, meanwhile, the amount of the gases stored in a fire-fighting system is also reduced greatly, the most important thing is to avoid the waste caused by all of the fire-extinguishing gases going into eruption instantaneously when the fire alarm occurs, and avoid the staff who do not have time to escape to suffer from suffocation and be endangered, thereby having higher energy saving and safe guaranty and reducing the cost of the fire-fighting system at the same time.

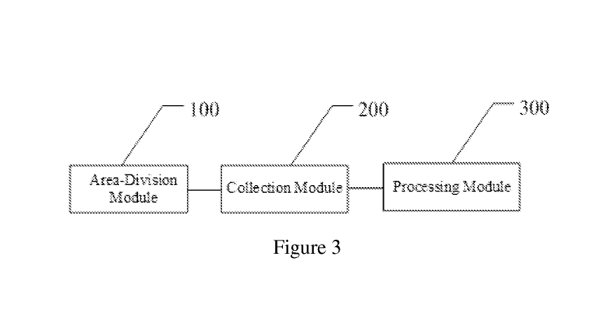

Referring to FIG. 3, to increase the use efficiency of the cold air in the cabinet body 2 to further obtain the effect of energy saving, the invention also includes a two-dimension dynamic air-transport energy-saving system for regulating the air transport in a sealed air-circulation system constituted by the air conditioner, the main air pipe of the air conditioner and the cabinet body. Wherein the inner portion of the cabinet body is divided into an air-transport area, a heat exchange area and an air-return area, a plurality of the apparatuses are placed at the heat exchange area. The two-dimension dynamic air-transport energy-saving system includes an area-division module 100, a collection module 200 and a processing module 300.

Specifically, the area-division module 100 is used for dividing the air-transport area into at least two sub air-transport units according to the number of the apparatuses at the heat exchange area and a heat load in a vertical direction, and for correspondingly providing at least two sub air-return units at the air-return area. As a plurality of the apparatuses are provided at the heat exchange area, and each the apparatus has different heat load and working temperature, in the example, the air-transport area is divided according to the working temperature of the apparatus, for example, the air-transport area are includes from up to down apparatus A1, apparatus A2, apparatus B1, apparatus B2 and apparatus C, furthermore, the working temperatures of the apparatuses A1 and A2 are the same, the working temperatures of the apparatuses B1 and B2 are the same, and the working temperature of the apparatus c is the same, then, the whole air-transport area can be divided into three sub areas in the vertical direction, that is, sub air-transport units: the air-transport unit of the first sub area corresponds to apparatuses A1 and A2; the air-transport unit of the second sub area corresponds to apparatuses B1 and B2; and the air-transport unit of the third sub area corresponds to apparatus C. Of course, the air-transport area can also be divided according to the equal volumes. There are many methods of area divisions, and details need not be enumerated one by one here. Similarly, corresponding to each the air-transport area, the corresponding air-return area is divided.

A collection module is used for collecting the temperature of the sub air-transport unit and the sub air-return unit as well as the heat load of the apparatus at the heat exchange area, and transmitting the collected data to the following processing module 300. Specifically, a temperature sensor and a humidity sensor can be provided in each the sub area (that is, the sub air-transport unit and the sub air-return unit) of the air-transport area and the air-return area, the apparatus (for example, a server) of the heat exchange area is generally provided with a collector for collecting the temperature, the heat load and other data. The collected data is transmitted to the processing module 300 via a wireless manner or a wired manner.

the processing module 300 is used for regulating the air transport quantity of each the sub air-transport unit in a horizontal direction and the air transport quantity of the air-transport area in the vertical direction in the real time according to the collected data and the preset data. Furthermore, the processing module is also used for regulating the air-return quantity of each the sub air-return unit according to the collected data and the preset data in the real time. Specifically, a high-efficiency cooling parallel air distribution is realized in a horizontal cross section direction, and hierarchical variable-air-volume differentiation cooling (that is, two-dimension dynamic air transport) is realized in a vertical cross section direction. Meanwhile, the dynamic matching of the load and cold supply of the two-dimension space of the cabinet is realized. According to the different temperature requirements of the each cabinet, multiple-temperature area differentiated cold supply of different cabinets can still be selected, thus greatly increasing the utilization efficiency of the cold energy.

Furthermore, the cold air of each the sub air-transport unit becomes hot air after passing through the corresponding apparatus, passes its corresponding sub air-return unit and returns back to the air conditioner 4. An automatic regulation valve can still be provided on an air-return pipeline of each the sub air-return unit to regulate the air-return quantity.

In the solution, an intelligent control model can be provided, according to the collected data and the preset data, the air-transport quantity and the air-return quantity in the horizontal direction and the vertical direction are regulated in the real time, to meet the working requirements of the apparatus corresponding to each the sub air-transport unit, and make the working temperature and/or the humility be within the preset range. The followings are the specific description of the intelligent control model:

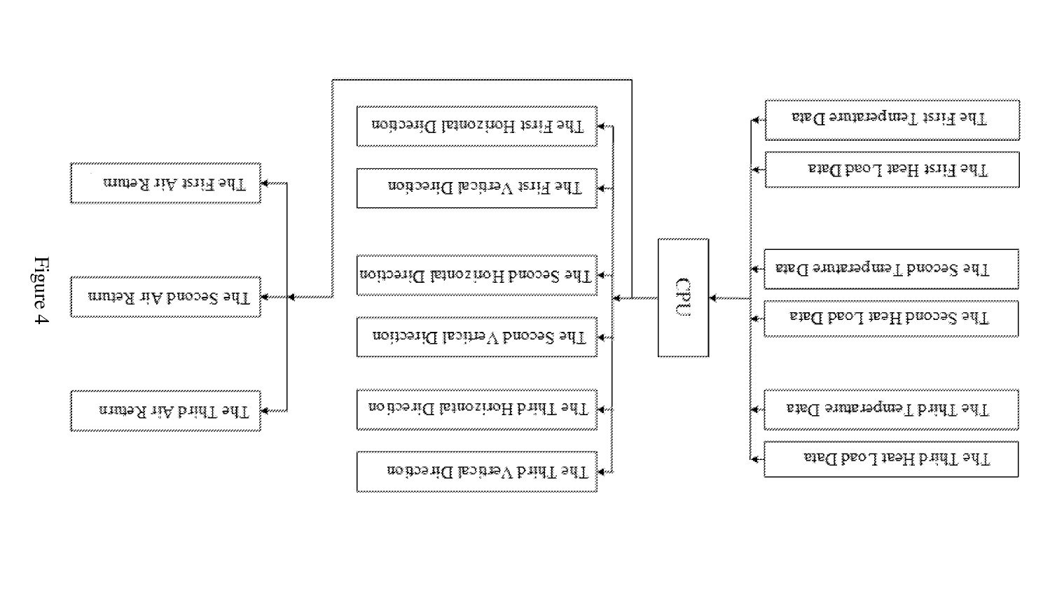

As shown in FIG. 4, in this example, the whole air-transport area is divided into three sub areas in the vertical direction. The temperature data (which are shown by the first temperature data in the figure) and the heat load data (which are shown by the first heat load data in the figure) of the apparatus collected by the air-transport unit of the first sub area are transmitted into the CPU of a control module, meanwhile, the temperature data (which are shown by the second temperature data in the figure) and the heat load data (which are shown by the second heat load data in the figure) of the apparatus collected by the air-transport unit of the second sub area, as well as the temperature data (which are shown by the third temperature data in the figure) and the heat load data (which are shown by the third heat load data in the figure) of the apparatus collected by the air-transport unit of the third sub area are transmitted into the CPU of the control module. the first, the second and the third temperature data as well as the first, the second and the third heat load data in the CPU are compared with the preset data, the air-transport quantity of the first, the second and the third sub air-transport units in the horizontal direction, the air-transport quantity of the air-transport area in the vertical direction and the air-return quantity of each the sub air-return unit (which are shown by the first horizontal direction, the first vertical direction, the second horizontal direction, the second vertical direction, the third horizontal direction, the third vertical direction, the firs air return, the second air return and the third air return in the figure, respectively) are output according to the preset conditions.

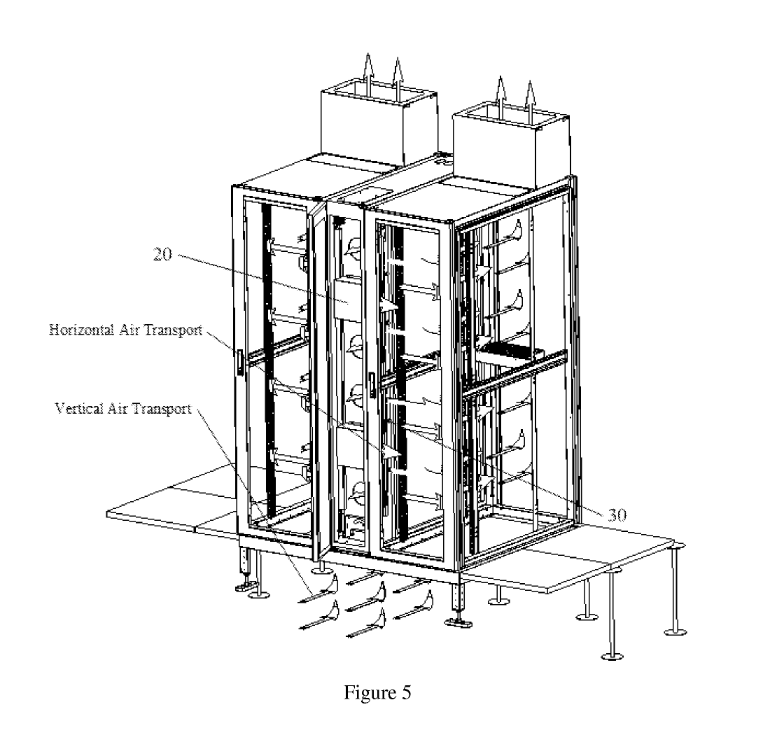

When the air pressure and air quantity transported under the floor cannot meet the actual cooling (heat dissipation) requirement of the apparatus in the cabinet, the two-dimension dynamic air-transport energy-saving system of the invention rapidly adjusts the working conditions by a two-dimension dynamic manner according to detected data. Please continue to refer to FIG. 5, FIG. 5 is a diagram according to an example of the two-dimension dynamic air-transport energy-saving system of the invention. as shown in figure, the two-dimension dynamic air-transport energy-saving system includes horizontal air transport and vertical air transport, the vertical air transport enters into the corresponding air-transport area via the air flow in a common air passage through an air-guide hole 30 provided at the side of the air-transport area. The horizontal air transport is carried out via a horizontal air-transport device 20 of the air-transport unit of each the sub area correspondingly, in this example, the cabinet is divided into two air-transport units of the sub area, the air-transport unit of each the sub area is provided with a corresponding horizontal air-transport device 20. The air-transport quantity in the vertical direction is regulated through the regulation of a variable-air-volume module at the bottom and the regulation of the size of the air-guide hole at the side. In the horizontal direction, the air-transport device 20 connected with an air pool changes the air-transport quantity in the horizontal direction.

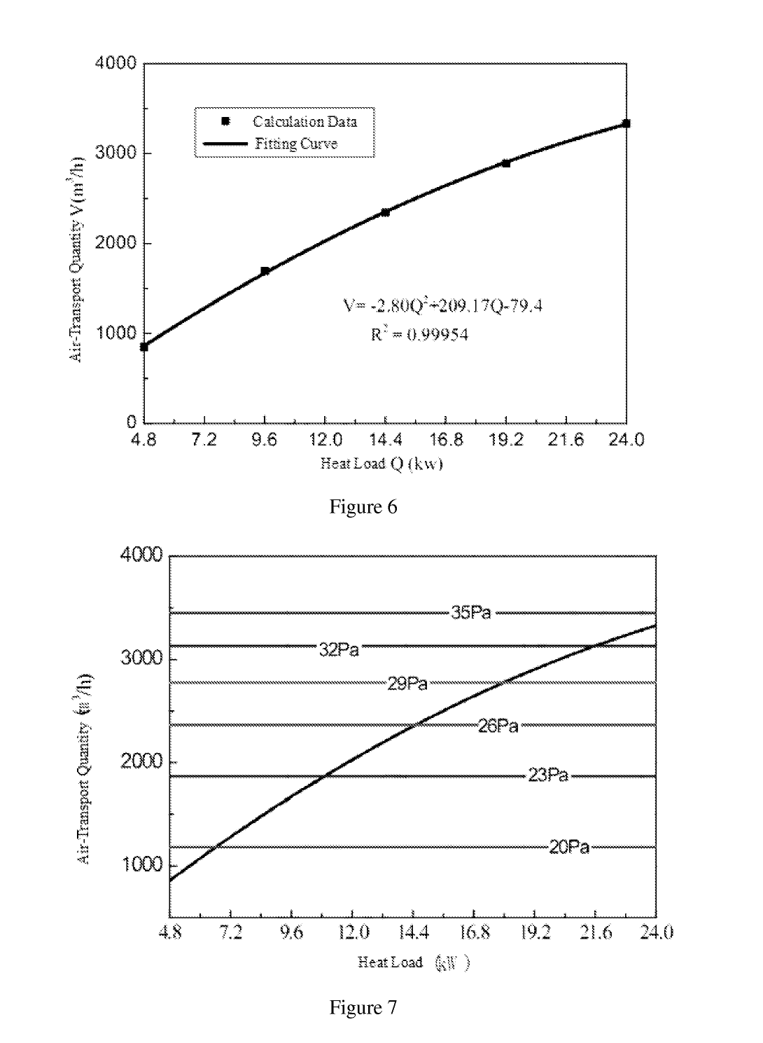

The key point of the invention is that the air-transport quantity is dynamically regulated in the real time according to the heat load and temperature requirements of the apparatus of the different layers in each the cabinet, to realize two-dimension dynamic air transport and meet the requirement of the differentiation cold supply, thereby increasing the unitization efficiency of the cold air. With research and a large number of experiments, it is found that the heat load and the air-transport quantity have a certain relation. The description is carried out according to a following specific example: If the temperature of inlet air is 23° C., when the average temperature of an air-outlet opening of the cabinet is not larger than 38° C.k, the result of the minimum air-transport quantity needed by the two-dimension dynamic air-transport energy-saving system is shown in FIG. 6. Wherein, the points in the figure are simulated calculation results, and the curve is a nonlinear fitting result, the relation between the air transport and the load (hereafter referred to as the heat load) of the two-dimension dynamic air-transport energy-saving system is shown in the following:

V=−2.80Q²+209.17Q−79.4

Wherein V is the air-transport quantity of the system, and its unit is m³/h; Q is the load of the cabinet, and its unit is kw.

The air transport in the vertical direction enters into the air-transport area via the air flow in the common air passage through the air-guide hole provided at the side of the air-transport area, the air-transport quantity in the vertical direction is regulated through the regulation of the variable-air-volume module at the bottom and the regulation of the size of the air-guide hole at the side. In the horizontal direction, each the horizontal air-transport device connected with the air pool corresponds to one sub air-transport unit. That is, after the air-transport unit is divided, each the sub air-transport unit corresponds to one variable-air-volume module (for example, a frequency conversion blower), the air-transport quantity in the horizontal direction is changed by the regulation of the frequency of each the frequency conversion blower.

The two-dimension dynamic air-transport energy-saving system and an air conditioner system are in combined operation, and transport the cold air into the cabinet through the air-transport pressure (for example, the air-transport pressure is the static pressure under the floor), the air-transport quantity of the two-dimension air-transport energy-saving system is closely related to the air-transport pressure, as shown in FIG. 7. The relation of the static pressure and the air quantity is a straight line parallel to a horizontal axis, the crossing point of the straight line and the air-transport quantity of the two-dimension air-transport energy-saving system is a starting critical point of the system, when the air quantity corresponding to the static pressure is larger than that of the two-dimension air-transport energy-saving system, the two-dimension air-transport energy-saving system is not needed to start, the cold air can be transported into the cabinet by the air-transport pressure of the refrigeration system; that is, to the right side of the crossing point in FIG. 7, the two-dimension air-transport energy-saving system is operated, while to the left side of the crossing point, the refrigeration system is operated.

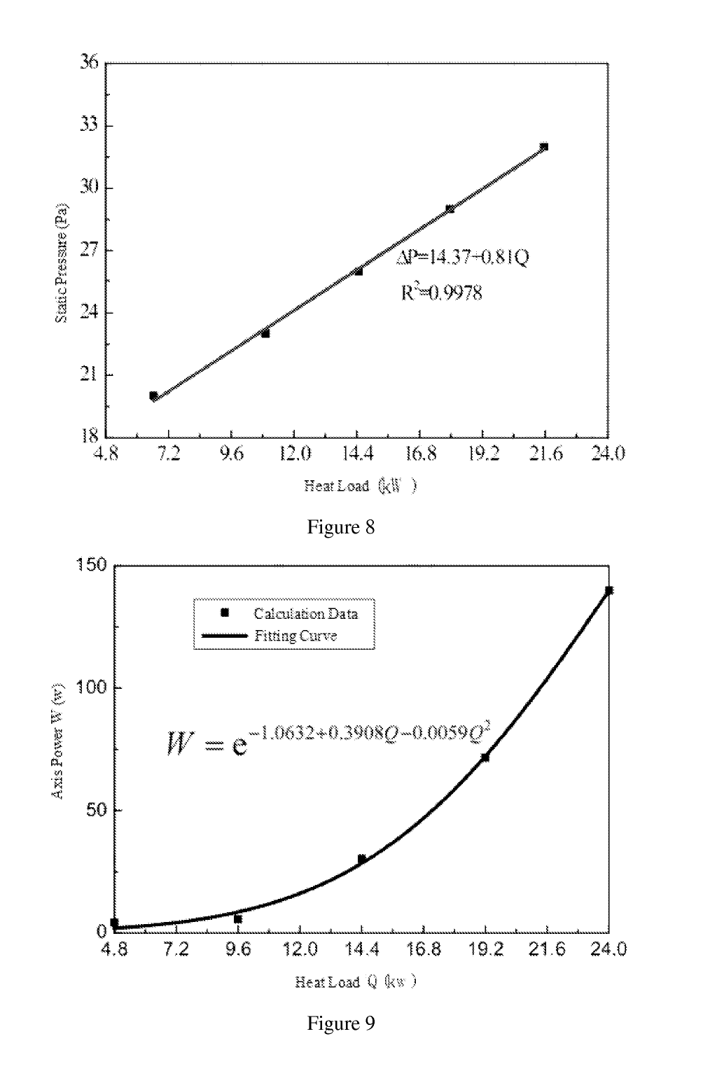

The relation between the air-transport pressure of the refrigeration system and the heat load in the cabinet is shown in FIG. 8.

That is, ΔP=14.37+0.81 Q;

wherein ΔP is the air-transport pressure (that is, the static pressure) of the refrigeration system, and its unit is Pa; Q is the heat load in the cabinet, and its unit is kw.

In conclusion, according to different loads, the distributions of an air flow field and a temperature field in the cabinet, the change relation of the air-transport quantity and the heat load of the two-dimension air-transport energy-saving system, as well as the change relation of the energy consumption of a simulated calculation system and the load of the cabinet are shown in FIG. 9. Wherein the points in the figure are the results of the simulated calculation, the curve is the nonlinear fitting result, the relation of the power consumption and the load of the two-dimension air-transport energy-saving system is shown in the following formula:

W=e^{-1.0632+0.3908Q-0.0059Q}^{²}

Wherein, W is the energy consumption of the system, its unit is w; Q is the load of the cabinet, and its unit is kw. therefore, the energy consumption of the two-dimension air-transport energy-saving system is changed with the increase of the load, as shown in FIG. 9, the system has the maximum energy consumption of 150 w under different heat loads, at this time, the output cold quantity can be 24 kw, compared with the energy consumption of the traditional refrigeration system, the energy consumption can be ignored. When the system and the traditional refrigeration system are in the combined operation, they increase the air-return temperature of the refrigeration system, the heat transfer efficiency of an evaporator of the refrigeration system, the evaporation quantity and refrigeration quantity of the refrigeration system, and the energy efficiency ratio of the refrigeration system.

Furthermore, the two-dimension air-transport energy-saving system also includes one static elimination module. The static elimination module makes ions in an air flow to be neutral, eliminates the hidden dangers and hazards of the apparatus caused by the static, maintains the working quality of the apparatus, and extends the service life of the apparatus.

The two-dimension air-transport energy-saving system of the invention is used for the energy saving of the refrigeration system, is used with the combination with the refrigeration system, integrally processes the air-transport quantity and air-return quantity of the refrigeration system, increases the air-return temperature of the evaporation side of the refrigeration system, increases the heat exchange efficiency of the refrigeration system and hence increases the energy efficiency ratio of the refrigeration system.

The two-dimension air-transport energy-saving system has the following working principle: the refrigeration system transports the cold air into an empty space of the floor, the air-transport pressure transports the cold air into the cabinet again, the two-dimension air-transport energy-saving system automatically adjusts the air-transport quantity and the air-transport pressure according to the temperature and heat load data, the hot air after heat exchange returns back to the evaporator of the refrigeration system after being processed by an air-return system, such circulation and repetition realize the cooling and energy saving in the cabinet. From experiments, the two-dimension air-transport energy-saving system can increase the air-return temperature of the refrigeration system, increase the utilization ratio of the cold quantity, hence greatly decrease the energy consumption of a refrigeration apparatus in a communication machine room, and meet the safe operation of an electronic servicer in the communication machine room; the two-dimension air-transport energy-saving system can increase the air-return temperature of the refrigeration system by 10° C. and increase the energy efficiency ratio of the refrigeration system by about 25.6%, the energy efficiency ratio of the operation of the system is calculated based on the following formula:

$$EER = \frac{{Q}_{r}}{W}$$

Wherein Qᵣ is the refrigeration quantity of the system of the air conditioner, and its unit is kw; W is the energy consumption of the operation of the system of the air conditioner, and its unit is kw.

The increase of the air-return temperature of the operation of the system can increase the heat transfer temperature difference of a refrigerant of the evaporator and the air, increase the heat exchange quantity of the evaporator (that is, the refrigeration quantity of the system of the air conditioner in the formula), and hence increase the energy efficiency ratio of the system. Wherein the formula only considers the heat exchange quantity of the evaporator, the calculation result is lower than the energy efficiency of the actual operation. in actual operation, the increase in the temperature of the room can still decrease the heat of a building enclosure, decrease the cold load of the data center and decrease the energy consumption of the operation of the air conditioner. According to statistic, if the temperature in the room is increased by 1° C., the energy consumption of the refrigeration system can be decreased by 5%-8%. The two-dimension air-transport energy-saving system can increase the air-return temperature of the refrigeration system by about 10° C., that is, the system can decrease the energy consumption of the system of the air conditioner by 50%-80%, which has great energy saving potential.

In summary, the two-dimension dynamic air-transport energy-saving system of the invention divides the air-transport area into at least two sub air-transport units according to the apparatus at the heat exchange area in the vertical direction, provides the sub air-return unit at the air-return area correspondingly, then collects the temperature of the sub air-transport unit and of the sub air-return unit as well as the heat load of the apparatus at the heat exchange area in the real time, and regulates the air-transport quantity of each the sub air-transport unit in the horizontal direction, the air-transport quantity of the air-transport area in the vertical direction and/or the air-return quantity of each the sub air-return unit according to the collected data and the preset data in the real time. It optimizes the air efficiency to realize a significant reduction in the energy consumption of the air conditioner under the premise of the needed temperature of each the apparatus of the heat exchange area, the system can reduce 50%-80% of the energy consumption of the system of the air conditioner and obtain the object of energy saving and environmental protection.

The above examples merely show several embodiments of the invention, the description is more specific and detailed, but cannot be hence understood to limit the patent scope of the invention. It should be pointed out that those skilled in the art can also make a plurality of modifications and improvement without departing from the concept of the invention, which all belong to the protection scope of the invention. Therefore, for the protection scope of the patent of the invention, the appended claims should prevail.

What is claimed is:

1. An intelligent combination-type energy-saving cabinet, comprising:
one or more cabinet bodies;
a main air pipe of an air conditioner connected with the air conditioner and each the cabinet body, the air conditioner, the main air pipe of the air conditioner and the cabinet body constituting one sealed air-circulation system; and
a two-dimension dynamic air-transport energy-saving system for regulating the air-transport of the sealed air-circulation system constituted by the air conditioner, the main air pipe of the air conditioner and the cabinet body;
wherein the inner portion of the cabinet body is divided into an air-transport area, a heat exchange area and an air-return area, a plurality of apparatuses are placed at the heat exchange area;
the two-dimension dynamic air-transport energy-saving system comprises:
an area-division module for dividing the air-transport area into at least two sub air-transport units according to the number of the apparatuses at the heat exchange area and a heat load in a vertical direction, and correspondingly providing at least two sub air-return units at the air-return area;
a collection module for collecting the temperature of the sub air-transport unit and the sub air-return unit as well as the heat load of the apparatus at the heat exchange area in real time, and transmitting the collected data to a following processing module; and
the processing module for regulating the air-transport quantity of each the sub air-transport unit in a horizontal direction and the air-transport quantity of the air-transport area in the vertical direction in the real time according to the collected data and the preset data.

2. The intelligent combination-type energy-saving cabinet of claim 1, wherein the processing module is also used for regulating the air-return quantity of each the sub air-return unit according to the collected data and the preset data in the real time.

3. The intelligent combination-type energy-saving cabinet of claim 1, wherein the processing module comprises:
a first sub processing unit for regulating the air-transport quantity according to the relation between a preset heat load and the air-transport quantity in the real time, wherein the relation between the air-transport quantity and the heat load is shown in the following formula:
V=−2.80Q²+209.17Q−79.4
wherein V is the air-transport quantity of a system, and its unit is m³/h; Q is the heat load, and its unit is kw.

4. The intelligent combination-type energy-saving cabinet of claim 1, wherein the processing module comprises:
a second processing unit used for regulating the air-transport quantity of the sub air-transport unit in the horizontal direction according to the air-transport quantity of the air-transport area in the vertical direction;
the relation between an air-transport pressure of a refrigeration system and the heat load in the cabinet is shown in the following:
ΔP=14.37+0.81Q
wherein ΔP is the air-transport pressure of the refrigeration system, and its unit is Pa; Q is the heat load in the cabinet, and its unit is kw.
